(19) United States
(12) Patent Application Publication
(10) Pub. No.: US 2026/0363131 A1
(43) Pub. Date: Nov. 12, 2026

(54) PACKAGE STRUCTURE

(71) Applicant: InnoLux Corporation, Miao-Li County (TW)

(72) Inventors: Chieh-Chen FU, Miao-Li County (TW); Wei-Yuan CHENG, Miao-Li County (TW); Chih-Chao CHUANG, Miao-Li County (TW); Yueh-Rong WANG, Miao-Li County (TW)

(73) Assignee: InnoLux Corporation, Miao-Li County (TW)

(21) Appl. No.: 19/642,592

(22) Filed: Apr. 8, 2026

Related U.S. Application Data
(60) Provisional application No. 63/801,752, filed on May 7, 2025.

(30) Foreign Application Priority Data
Mar. 5, 2026 (TW) 115107984

(51) Int. Cl. H10W 74/10; H10W 72/00; H10W 90/00; H10W 20/20; H10W 46/00; H10W 70/08; H10W 74/47; H10W 90/22

(52) U.S. Cl. CPC H10W 74/121; H10W 72/823; H10W 90/401; H10W 20/211; H10W 46/301; H10W 70/08; H10W 74/47; H10W 90/22

(57) ABSTRACT

The present disclosure provides a package structure, including an electronic unit, a plurality of third metal pillars, and a first encapsulation layer. The electronic unit comprises a die, a first protective layer, a second protective layer, a third protective layer, a first metal pillar, and a second metal pillar. The die has a first surface, an opposite second surface, and a side surface connecting the first surface and the second surface. The first, second, and third protective layers surround the die. The first metal pillar is disposed on the first surface and the second metal pillar is disposed on the second surface, with both being electrically connected to the die. The plurality of third metal pillars are disposed on at least one side of the electronic unit. The first encapsulation layer surrounds the first, second, and third protective layers of the electronic unit.

### CROSS REFERENCE TO RELATED APPLICATION

This application claims the benefit of U.S. Provisional Application No. 63/801,752, filed on May 7^{th}, 2025. The content of the application is incorporated herein by reference.

### BACKGROUND OF THE DISCLOSURE

### 1. Field of the Disclosure

The present disclosure relates to a package structure, and more particularly to a package structure that includes an electronic unit having protective layers surrounding a die.

### 2. Description of the Prior Art

In recent years, the manufacturing and production technologies of electronic devices often include processes for packaging or redistributing lines of electronic components. As electronic components in electronic devices gradually trend towards miniaturization and high density, the design of package structures for integrating electronic components and circuits remains one of the important issues today.

### SUMMARY OF THE DISCLOSURE

An objective of the present disclosure is to provide a package structure, in which an electronic unit includes a first protective layer, a second protective layer, and a third protective layer surrounding a die, and a first encapsulation layer surrounds the aforementioned protective layers, to enhance the protective effect on the die, thereby improving the reliability of the electronic unit and its related package structure.

An embodiment of the present disclosure provides a package structure, which includes an electronic unit, a plurality of third metal pillars, and a first encapsulation layer. The electronic unit includes a die, a first protective layer, a second protective layer, a third protective layer, a first metal pillar, and a second metal pillar. The die has a first surface, a second surface, and a side surface, the first surface is opposite to the second surface, and the side surface connects the first surface and the second surface. The first protective layer, the second protective layer and the third protective layer surround the die. The first metal pillar is disposed on the first surface and electrically connected to the die. The second metal pillar is disposed on the second surface and electrically connected to the die. The third metal pillars are disposed on at least one side of the electronic unit. The first encapsulation layer surrounds the first protective layer, the second protective layer and the third protective layer of the electronic unit.

### BRIEF DESCRIPTION OF THE DRAWINGS

FIG. 1 is a schematic cross-sectional view of an electronic unit in a process step according to an embodiment of the present disclosure.

FIGS. 2-4 are schematic cross-sectional views of some variant embodiments of the electronic unit of the present disclosure.

FIG. 5 is a schematic cross-sectional view of a package structure in a process step according to a first embodiment of the present disclosure.

FIG. 6 is a partial schematic process view of a method for manufacturing the package structure according to an embodiment of the present disclosure.

FIG. 7 is a partial schematic cross-sectional view of a package structure according to a second embodiment of the present disclosure.

FIG. 8 is a partial schematic cross-sectional view of a package structure according to a third embodiment of the present disclosure.

FIG. 9 is a schematic cross-sectional view of a package structure according to a fourth embodiment of the present disclosure.

FIG. 10 is a schematic cross-sectional view of a package structure according to a fifth embodiment of the present disclosure.

### DETAILED DESCRIPTION

The multiple drawings in the present disclosure only depict a part of a device or structure, and specific elements in the drawings are not drawn to actual scale. In addition, the number and size of each element in the figures are for illustrative purposes only and are not intended to limit the scope of the present disclosure.

Certain terms are used in the present disclosure to refer to specific elements. Those skilled in the art should understand that electronic device manufacturers may refer to the same element by different names. When the terms "comprising," "including," "containing," and/or "having" are used in this specification, they specify the presence of stated features, regions, steps, operations, and/or elements, but do not preclude the presence or addition of one or more other features, regions, steps, operations, elements, and/or combinations thereof.

When an element or layer is referred to as being "on" or "connected to" another element or layer, it can be directly on or directly connected to the other element or layer, or intervening elements or layers may be present. In contrast, when an element is referred to as being "directly on" or "directly connected to" another element or layer, there are no intervening elements or layers present.

The directional terms mentioned herein, such as "upper," "lower," "front," "back," "left," "right," etc., are only for reference to the directions of the appended drawings. Therefore, the directional terms used are for illustration and not to limit the present disclosure.

The terms "approximately," "equal to," "equivalent," or "same," "substantially," or "generally" are generally interpreted to be within 20% of a given value or range, or interpreted to be within 10%, 5%, or 0.5% of a given value or range.

The use of ordinal numbers such as "first," "second," etc. in the specification and claims to modify elements does not in itself imply or represent any preceding ordinal numbers for the element(s), nor does it represent the order of one element with respect to another, or the order of a manufacturing method. The use of these ordinal numbers is only to clearly distinguish an element with a certain name from another element with the same name. The claims and the specification may not use the same terms; accordingly, a first component in the specification may be a second component in the claims.

The package structure described in the present disclosure can be applied to high-speed computing modules, power modules, semiconductor devices, display devices, light-emitting devices, back-light devices, antenna devices, sensing devices, tiling devices, or other suitable electronic devices, but is not limited thereto. The display device can be a non-self-emissive display device or a self-emissive display device. The antenna device can be a liquid crystal type antenna device or a non-liquid crystal type antenna device. The sensing device can be a sensing device for sensing capacitance, light, thermal energy, or ultrasound, but is not limited thereto. The electronic device can include electronic components, which can include passive components, active components, and/or semiconductor components, such as capacitors, resistors, inductors, diodes, transistors, integrated circuits, etc. The diode can include a light-emitting diode, a photodiode, or a varactor diode. The semiconductor component can include a semiconductor layer or a component fabricated through a semiconductor process, but is not limited thereto.

The manufacturing process of the package structure in the present disclosure can be applied to, for example, a wafer-level package (WLP) process or a panel-level package (PLP) process, wherein the wafer-level package or panel-level package process can include a chip-first process or a chip-last process, but is not limited thereto. The package structure can include a system on a chip (SoC), a system in a package (SiP), an antenna in package (AiP), co-packaged optics (CPO), or various combinations of the above devices, but is not limited thereto.

It should be understood that features from several different embodiments can be substituted, reorganized, and mixed to complete other embodiments without departing from the spirit of the present disclosure.

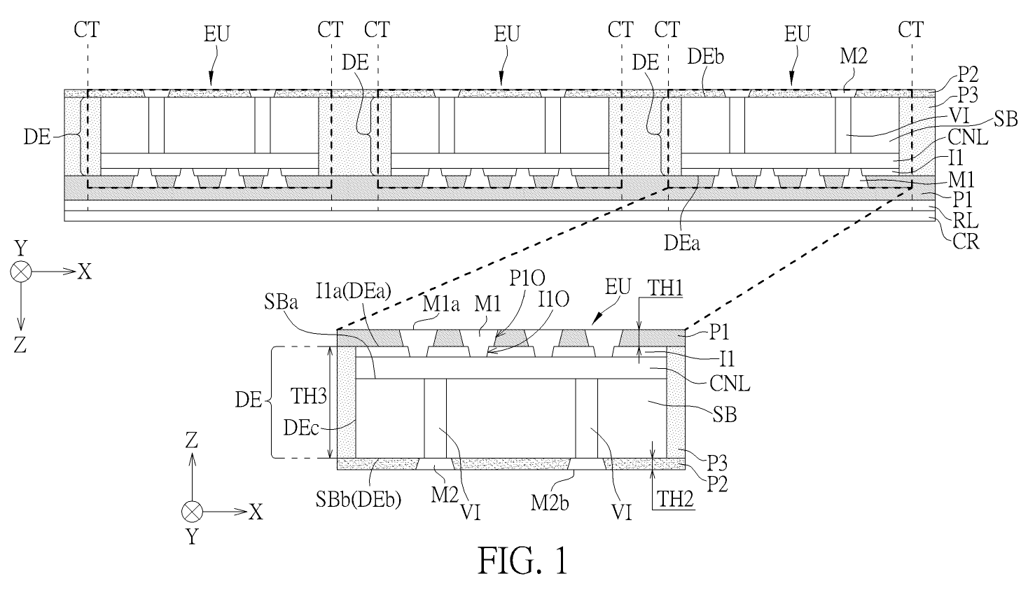

Please refer to FIG. 1, which is a schematic cross-sectional view of an electronic unit in a process step according to an embodiment of the present disclosure. Therein, after removing the release layer RL, the carrier CR, and a portion of the first protective layer P1, cutting is performed along multiple dicing lines CT shown in the upper cross-sectional view of FIG. 1 to obtain multiple electronic units EU. The detailed process steps of the electronic unit EU will be further described in subsequent paragraphs. The cross-sectional structure of each electronic unit EU is as shown in the range of the dashed box in the upper cross-sectional view of FIG. 1, and the lower side of FIG. 1 shows a schematic cross-sectional view of the manufactured electronic unit EU after being flipped upside down. As shown in the lower cross-sectional view of FIG. 1, the electronic unit EU includes a die DE, a first protective layer P1, a second protective layer P2, a third protective layer P3, at least one first metal pillar M1, and at least one second metal pillar M2. The die DE has a first surface DEa (or referred to as an upper surface), a second surface DEb (or referred to as a lower surface), and a side surface DEc. The first surface DEa is opposite to the second surface DEb, and the side surface DEc connects the first surface DEa and the second surface DEb. The first protective layer P1, the second protective layer P2, and the third protective layer P3 surround the die DE, wherein the third protective layer P3 can surround the side surface DEc of the die DE, the first protective layer P1 can cover the first surface DEa, and the second protective layer P2 can cover the second surface DEb. The at least one first metal pillar M1 is disposed on the first surface DEa and electrically connected to the die DE. The at least one second metal pillar M2 is disposed on the second surface DEb and electrically connected to the die DE. Moreover, the first protective layer P1 can expose the first metal pillar M1, and the second protective layer P2 can expose the second metal pillar M2. Specifically, the first metal pillar M1 can penetrate the first protective layer P1, such that the first protective layer P1 exposes an upper surface M1a of the first metal pillar M1, and the second metal pillar M2 can penetrate the second protective layer P2, such that the second protective layer P2 exposes a lower surface M2b of the second metal pillar M2.

According to the electronic unit EU shown in the lower cross-sectional view of FIG. 1, the die DE can include a first insulating layer I1, a circuit layer CNL, a substrate SB, and a through-hole structure VI. The circuit layer CNL is disposed on an upper surface SBa of the substrate SB. The first insulating layer I1 is disposed on the circuit layer CNL, and the circuit layer CNL can, for example, include at least one insulating layer and at least one conductive layer stacked along a direction Z. Herein, the direction Z can be a normal direction of the first surface DEa or the second surface DEb, or the direction Z can be a normal direction of the upper surface SBa or a lower surface SBb of the substrate SB, and the direction Z can be parallel to a top-view direction of the electronic unit EU. Furthermore, the direction Z is perpendicular to a direction X and a direction Y, and the direction X is perpendicular to the direction Y and can be a horizontal direction. An upper surface I1a (or can be referred to as an outer surface) of the first insulating layer I1 can be the first surface DEa of the die DE, and the lower surface SBb of the substrate SB can be the second surface DEb of the die DE. The first insulating layer I1 can have a plurality of openings I1O to expose the circuit layer CNL therebelow. The first protective layer P1 can be disposed on the upper surface I1a of the first insulating layer I1 and have a plurality of openings P1O, and each opening P1O can at least partially overlap an opening I1O in the direction Z. A portion of each first metal pillar M1 is disposed in the opening I1O of the first insulating layer I1, another portion thereof is disposed in the opening P1O of the first protective layer P1, and the first metal pillar M1 can be electrically connected to the circuit layer CNL.

One or more through-hole structures VI can be disposed on a side of the circuit layer CNL opposite to the first insulating layer I1 and penetrate the substrate SB. Each through-hole structure VI can be formed by filling a conductive material into a through-hole in the substrate SB, and the through-hole structure VI can be electrically connected to the circuit layer CNL. The second protective layer P2 can be disposed on the lower surface SBb of the substrate SB and have a plurality of openings P2O. Each opening P2O can at least partially overlap a through-hole structure VI in the direction Z, and each second metal pillar M2 can be disposed in the opening P2O and electrically connected to the through-hole structure VI. That is, the second metal pillar M2 can be electrically connected to the circuit layer CNL through the through-hole structure VI. The third protective layer P3 can surround and cover the side surfaces of the first insulating layer I1, the circuit layer CNL, and the substrate SB.

In some embodiments, the first protective layer P1, the second protective layer P2, and the third protective layer P3 can include an organic material, such as epoxy molding compound (EMC), polyimide (PI), Ajinomoto buildup film (ABF), or other suitable materials. As shown in the lower cross-sectional view of FIG. 1, in the direction Z, the first protective layer P1 has a thickness TH1, and the second protective layer P2 has a thickness TH2, wherein the thickness TH1 and the thickness TH2 can each be greater than or equal to 5 micrometers (µm) and less than or equal to 15 micrometers, but are not limited thereto. The die DE has a thickness TH3 in the direction Z, wherein the thickness TH3 can be greater than or equal to 25 micrometers and less than or equal to 100 micrometers, but is not limited thereto. When the thickness TH3 of the die DE is thicker, the first protective layer P1 and the second protective layer P2 also need to have a greater thickness to protect the die DE. Herein, a ratio of the thickness TH1 of the first protective layer P1 to the thickness TH3 of the die DE can be greater than or equal to 0.05 and less than or equal to 0.6 (i.e., 0.05 ≤ TH1/TH3 ≤ 0.6), and a ratio of the thickness TH2 of the second protective layer P2 to the thickness TH3 of the die DE can be greater than or equal to 0.05 and less than or equal to 0.6 (i.e., 0.05 ≤ TH2/TH3 ≤ 0.6). In some embodiments, the first insulating layer I1 can include an inorganic material, such as silicon oxide (SiOx), silicon nitride (SiNx), silicon oxynitride (SiOxNx), or other suitable materials. In other embodiments, the first protective layer P1, the second protective layer P2, and the third protective layer P3 can include an inorganic material, but are not limited thereto. The materials of the first metal pillar M1 and the second metal pillar M2 can include copper (Cu), titanium (Ti), aluminum (Al), molybdenum (Mo), nickel (Ni), ruthenium (Ru), tantalum (Ta), tungsten (W), other suitable conductive materials, or a combination of the above materials.

In some embodiments, the first protective layer P1, the second protective layer P2, and the third protective layer P3 can have a smaller Young's modulus to mitigate stress or impact generated during the process of the die DE, thereby achieving the effect of protecting the die DE. Specifically, a Young's modulus of the first protective layer P1 can be less than a Young's modulus of the first insulating layer I1 of the die DE, and the Young's modulus of the first protective layer P1 can be less than a Young's modulus of the substrate SB of the die DE. In addition, the Young's moduli of the second protective layer P2 and the third protective layer P3 can also be respectively less than the Young's moduli of the first insulating layer I1 and the substrate SB. For example, the Young's modulus of the substrate SB of the die DE can be 130 gigapascals (GPa) to 190 GPa, the Young's modulus of the first insulating layer I1 of the die DE can be 70 GPa to 90 GPa, and the Young's moduli of the first protective layer P1, the second protective layer P2, and the third protective layer P3 can be 3 GPa to 30 GPa, but are not limited thereto.

According to the embodiment shown in FIG. 1, a method for manufacturing the electronic unit EU can include the following steps. First, a plurality of dies DE can be provided. Each die DE, for example, includes a first insulating layer I1, a circuit layer CNL, a substrate SB, and a through-hole structure VI. The detailed structure and materials of the die DE can be referred to in the foregoing content and will not be repeated here. Then, the plurality of dies DE are attached to a carrier with their first surfaces DEa facing down and spaced from each other by a predetermined distance, through a release layer (not shown). Next, a third protective layer P3 is formed, causing the third protective layer P3 to surround the plurality of dies DE. Then, the entire structure including the plurality of dies DE and the third protective layer P3 is released from the carrier and flipped upside down. The third protective layer P3 is then attached to another carrier through another release layer with the first surfaces DEa facing up. Then, a plurality of first metal pillars M1 are formed on the first surfaces DEa of the dies DE, wherein each first metal pillar M1 can penetrate the first insulating layer I1 and be electrically connected to the circuit layer CNL. Next, a first protective layer P1 is formed, causing the first protective layer P1 to cover the first metal pillars M1 and the first surfaces DEa of each die DE. Then, the entire structure including the plurality of dies DE, the third protective layer P3, the first protective layer P1, and the first metal pillars M1 is released from the carrier and flipped upside down. The first protective layer P1 is then attached to yet another carrier CR through yet another release layer RL (shown on the upper side of FIG. 1) with the second surfaces DEb facing up. Then, the third protective layer P3 and the substrate SB of the die DE can be ground to expose the outer surfaces of the through-hole structures VI (i.e., the upper surfaces of the through-hole structures VI shown in the upper cross-sectional view of FIG. 1). Next, a plurality of second metal pillars M2 are formed on the second surfaces DEb of the dies DE, wherein each second metal pillar M2 can be electrically connected to a through-hole structure VI and electrically connected to the circuit layer CNL through the through-hole structure VI. Then, a second protective layer P2 is formed, causing the second protective layer P2 to cover the second metal pillars M2 and the second surfaces DEb of each die DE. Next, the second protective layer P2 can be ground to expose the outer surfaces of the second metal pillars M2 (i.e., the upper surfaces of the second metal pillars M2 shown in the upper cross-sectional view of FIG. 1), thereby forming the cross-sectional structure as shown on the upper side of FIG. 1. Then, the entire structure above the release layer RL in the upper cross-sectional view of FIG. 1 is released from the carrier CR and flipped upside down. The second protective layer P2 and the second metal pillars M2 are then attached to another carrier through yet another release layer with the first surfaces DEa facing up. Then, the first protective layer P1 can be ground to expose the upper surfaces M1a of the first metal pillars M1. Finally, cutting is performed at positions corresponding to the dicing lines CT and released from the carrier, thereby obtaining a plurality of electronic units EU as shown on the lower side of FIG. 1.

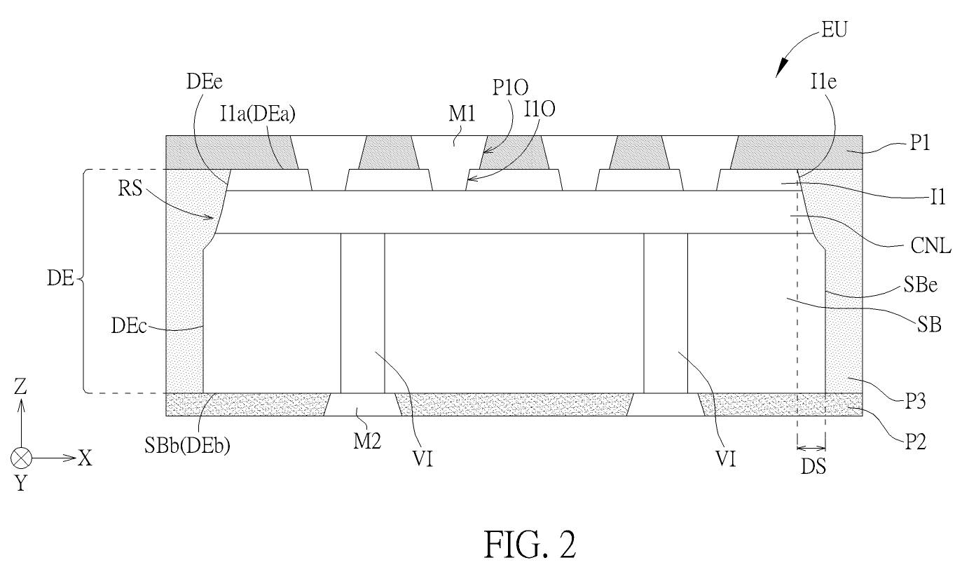

Please refer to FIGS. 2-4 . FIGS. 2-4 are schematic cross-sectional views of some variant embodiments of the electronic unit of the present disclosure. As shown in FIGS. 2,3 and 4, an edge DEe of the die DE can have a recess RS, and the third protective layer P3 can contact a surface of the recess RS, thereby increasing the adhesion between the third protective layer P3 and the die DE. Herein, the edge DEe of the die DE can be a corner region or an edge region of its side. For example, the recess RS can be formed through a dicing step during the singulation process of the die DE, but is not limited thereto. According to the embodiment shown in FIG. 2, edges of the first insulating layer I1, the circuit layer CNL, and the substrate SB of the die DE can be recessed inward to form the recess RS, and the third protective layer P3 can contact the side surfaces of the first insulating layer I1, the circuit layer CNL, and the substrate SB. In the cross-sectional view of the electronic unit EU as shown in FIG. 2, in the direction X, there is a distance DS between an edge I1e of the first insulating layer I1 and an edge SBe of the substrate SB, wherein the distance DS can be 0.1 micrometers to 30 micrometers, but is not limited thereto.

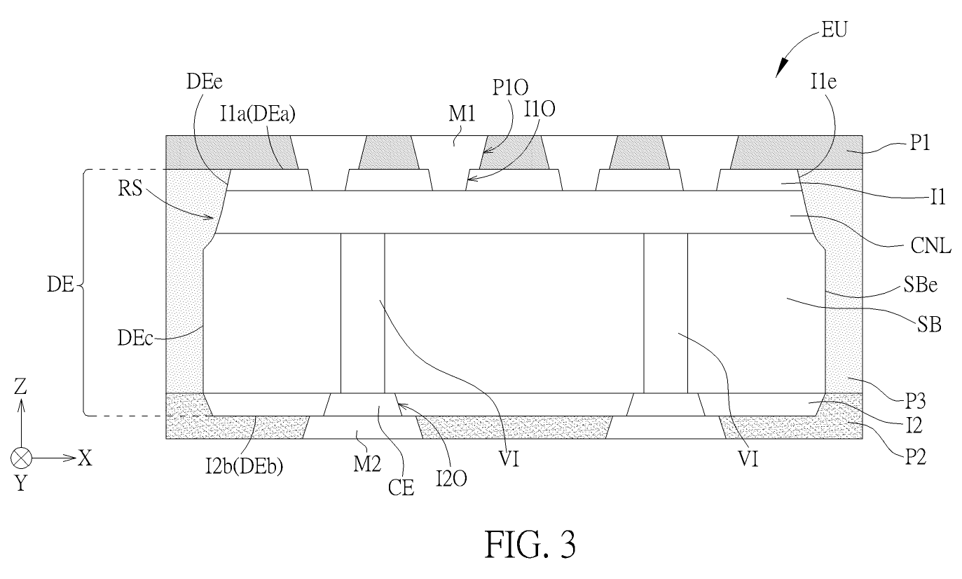

According to the embodiment shown in FIG. 3, the die DE can further include a second insulating layer I2 disposed on a side of the substrate SB opposite to the circuit layer CNL. A lower surface I2b (or can be referred to as an outer surface) of the second insulating layer I2 can be the second surface DEb of the die DE, and the second protective layer P2 is disposed on the lower surface I2b of the second insulating layer I2. The second insulating layer I2 can have a plurality of openings I2O, each opening I2O can at least partially overlap a through-hole structure VI in the direction Z, and the die DE can further include a plurality of conductive elements CE. Each conductive element CE can be disposed in an opening I2O and electrically connected to the through-hole structure VI. Each second metal pillar M2 can be disposed on a side of the conductive element CE opposite to the through-hole structure VI and electrically connected to the conductive element CE. That is, the second metal pillar M2 can be electrically connected to the circuit layer CNL through the conductive element CE and the through-hole structure VI.

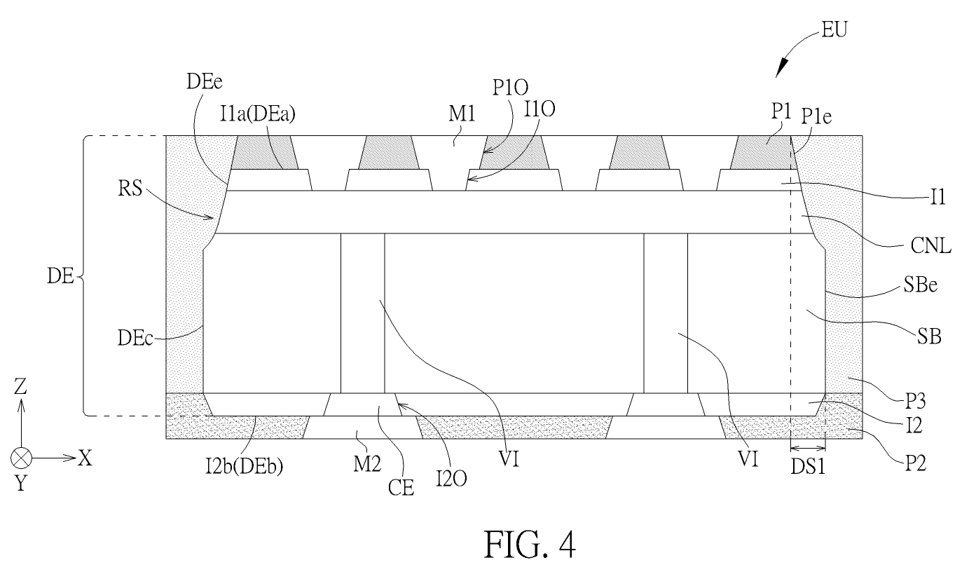

According to the embodiment shown in FIG. 4, an edge P1e of the first protective layer P1 and edges of the first insulating layer I1, the circuit layer CNL, and the substrate SB of the die DE can be recessed inward to form a recess RS, and the third protective layer P3 can contact the side surfaces of the first protective layer P1, the first insulating layer I1, the circuit layer CNL, and the substrate SB. In the cross-sectional view of the electronic unit EU as shown in FIG. 4, in the direction X, there is a distance DS1 between the edge P1e of the first protective layer P1 and an edge SBe of the substrate SB, wherein the distance DS1 can be 0.1 micrometers to 30 micrometers, but is not limited thereto. In the method for manufacturing the electronic unit EU shown in FIG. 4, the first protective layer P1 can be formed on the first insulating layer I1 before the singulation process of the die DE, and then the recess RS can be formed through a dicing step, but is not limited thereto.

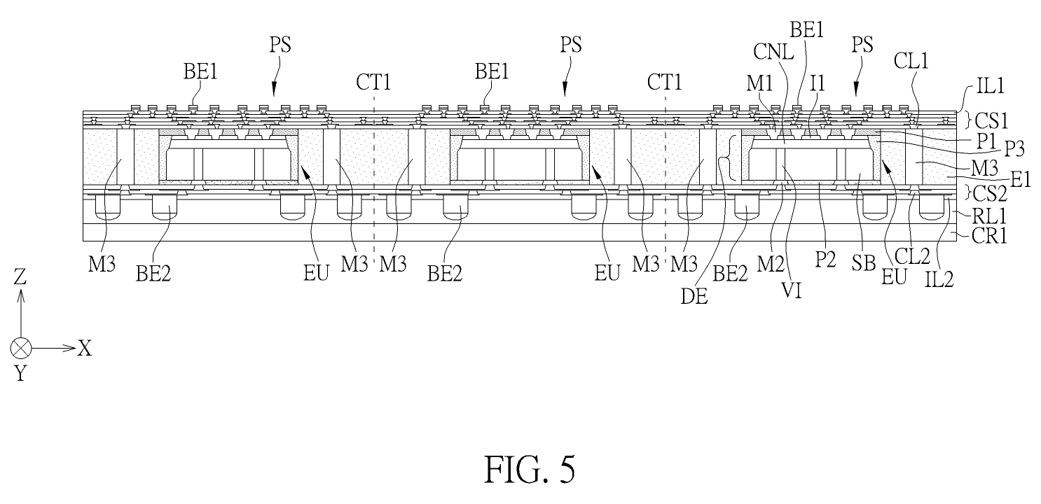

Please refer to FIG. 5, which is a schematic cross-sectional view of a package structure in a process step according to a first embodiment of the present disclosure. Therein, after removing the release layer RL1 and the carrier CR1, cutting is performed along multiple dicing lines CT1 shown in the cross-sectional view of FIG. 5 to obtain multiple package structures PS. The detailed process steps of the package structure PS will be further described in subsequent paragraphs. It should be noted that FIG. 5 showing the package structure PS including the electronic unit EU as shown in FIG. 2 is only an example, and the present disclosure is not limited thereto. In other embodiments, the package structure PS can include the electronic unit EU as shown in FIGS. 1,3 or 4,. As shown in FIG. 5, the package structure PS includes an electronic unit EU, a plurality of third metal pillars M3, and a first encapsulation layer E1. The components, materials, and detailed structure of the electronic unit EU can be referred to in the embodiment shown in FIG. 2, and will not be repeated here. The plurality of third metal pillars M3 are disposed on at least one side of the electronic unit EU, that is, the third metal pillars M3 can be disposed on the left side and/or the right side of the electronic unit EU. For example, the package structure PS can include two third metal pillars M3, respectively disposed on the left and right sides of the electronic unit EU, but is not limited thereto. The first encapsulation layer E1 surrounds the first protective layer P1, the second protective layer P2, and the third protective layer P3 of the electronic unit EU. The first encapsulation layer E1 can cover the side surfaces of the first protective layer P1, the second protective layer P2, and the third protective layer P3, that is, the first encapsulation layer E1 can surround and cover the side surface of the electronic unit EU and expose the upper surface and the lower surface of the electronic unit EU. Moreover, the first encapsulation layer E1 can surround the plurality of third metal pillars M3 to cover the side surfaces of the third metal pillars M3 and expose the upper surfaces and lower surfaces of the third metal pillars M3.

The material of the third metal pillars M3 can be referred to the materials of the first metal pillar M1 and the second metal pillar M2 in the aforementioned embodiments and will not be repeated here. The material of the first encapsulation layer E1 can include organic resin, epoxy resin, epoxy molding compound, ceramic, poly(methyl methacrylate) (PMMA), polydimethylsiloxane (PDMS), other suitable materials, or a combination of the above materials, but is not limited thereto.

According to the embodiment shown in FIG. 5, the package structure PS can further include a first circuit structure CS1 and a second circuit structure CS2, respectively disposed on opposite sides of the electronic unit EU. Specifically, the first circuit structure CS1 can be disposed on the upper side of the electronic unit EU and the third metal pillars M3, and the third metal pillars M3 and the first metal pillars M1 of the electronic unit EU can be respectively electrically connected to the first circuit structure CS1. The second circuit structure CS2 can be disposed on the lower side of the electronic unit EU and the third metal pillars M3, and the third metal pillars M3 and the second metal pillars M2 of the electronic unit EU can be respectively electrically connected to the second circuit structure CS2. In some embodiments, as shown in FIG. 5, the package structure PS can further include a plurality of first bonding elements BE1 and a plurality of second bonding elements BE2. The plurality of first bonding elements BE1 are disposed on a side of the first circuit structure CS1 opposite to the electronic unit EU and are electrically connected to the first circuit structure CS1. The plurality of second bonding elements BE2 are disposed on a side of the second circuit structure CS2 opposite to the electronic unit EU and are electrically connected to the second circuit structure CS2. Herein, the first bonding elements BE1 and the second bonding elements BE2 can be used to bond with other components, such as (but not limited to) a circuit board, electronic components, or other suitable components.

As shown in FIG. 5, the first circuit structure CS1 can include at least one insulating layer IL1 and at least one conductive layer CL1. In its stacking direction Z, multiple conductive layers CL1 can be electrically connected to each other through at least one through-hole in the insulating layer IL1. The lowermost conductive layer CL1 of the first circuit structure CS1 (i.e., the conductive layer CL1 closest to the electronic unit EU in the direction Z) can be electrically connected to the third metal pillars M3 and the first metal pillars M1 of the electronic unit EU. The uppermost conductive layer CL1 of the first circuit structure CS1 (i.e., the conductive layer CL1 farthest from the electronic unit EU in the direction Z) can be electrically connected to the first bonding elements BE1. The second circuit structure CS2 can include at least one insulating layer IL2 and at least one conductive layer CL2. In its stacking direction Z, multiple conductive layers CL2 can be electrically connected to each other through at least one through-hole in the insulating layer IL2. The uppermost conductive layer CL2 of the second circuit structure CS2 (i.e., the conductive layer CL2 closest to the electronic unit EU in the direction Z) can be electrically connected to the third metal pillars M3 and the second metal pillars M2 of the electronic unit EU. The lowermost conductive layer CL2 of the second circuit structure CS2 (i.e., the conductive layer CL2 farthest from the electronic unit EU in the direction Z) can be electrically connected to the second bonding elements BE2. That is, the plurality of first bonding elements BE1 can be electrically connected to the first metal pillars M1 and the third metal pillars M3 through the conductive layers CL1 in the first circuit structure CS1, and the plurality of second bonding elements BE2 can be electrically connected to the second metal pillars M2 and the third metal pillars M3 through the conductive layers CL2 in the second circuit structure CS2.

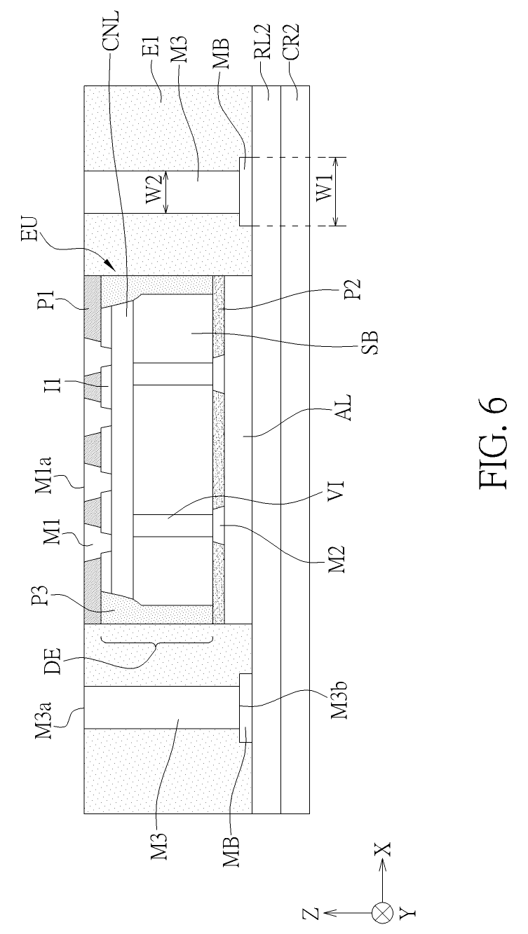

According to the embodiment shown in FIG. 5, a method for manufacturing the package structure PS can include the following steps. First, a release layer (e.g., the release layer RL2 shown in FIG. 6) can be formed on a carrier (e.g., the carrier CR2 shown in FIG. 6), and then a plurality of third metal pillars M3 are formed on the release layer, spaced from each other by a predetermined distance. Next, through an adhesive layer (e.g., the adhesive layer AL shown in FIG. 6), the outer surfaces of the second protective layers P2 (i.e., the surfaces away from the substrate SB) of a plurality of electronic units EU are attached to the release layer, such that each electronic unit EU is disposed on the carrier with the outer surface of the first protective layer P1 (i.e., the surface away from the circuit layer CNL) facing up, wherein each electronic unit EU can be located between two third metal pillars M3 in the direction X. Then, a first encapsulation layer E1 is formed, causing the first encapsulation layer E1 to surround the plurality of third metal pillars M3 and the first protective layer P1, the second protective layer P2, and the third protective layer P3 of each electronic unit EU. Next, the first encapsulation layer E1 can be ground to expose the surfaces of the first metal pillars M1 and the third metal pillars M3. Then, the entire structure including the plurality of electronic units EU, the plurality of third metal pillars M3, and the first encapsulation layer E1 is released from the carrier and flipped upside down. The entire structure is then attached to another carrier through another release layer with the outer surfaces of the second protective layers P2 facing up. Next, the first encapsulation layer E1 can be ground to expose the surfaces of the second metal pillars M2 and the third metal pillars M3. Then, the entire structure including the plurality of electronic units EU, the plurality of third metal pillars M3, and the first encapsulation layer E1 is released from the carrier and flipped upside down. The entire structure is then attached to yet another carrier through yet another release layer with the outer surfaces of the first protective layers P1 facing up. Next, a first circuit structure CS1 can be formed on one side of the plurality of electronic units EU and the third metal pillars M3, so that the first circuit structure CS1 is electrically connected to each of the third metal pillars M3 and the first metal pillars M1 of each electronic unit EU.

After forming the first circuit structure CS1, the entire structure including the plurality of electronic units EU, the plurality of third metal pillars M3, the first encapsulation layer E1, and the first circuit structure CS1 is released from the carrier and flipped upside down. The first circuit structure CS1 is then attached to another carrier through yet another release layer. Next, a second circuit structure CS2 can be formed on the other side of the plurality of electronic units EU and the third metal pillars M3 relative to the first circuit structure CS1, so that the second circuit structure CS2 is electrically connected to each of the third metal pillars M3 and the second metal pillars M2 of each electronic unit EU. Then, a plurality of second bonding elements BE2 can be formed on the second circuit structure CS2. Next, the entire structure including the plurality of electronic units EU, the plurality of third metal pillars M3, the first encapsulation layer E1, the first circuit structure CS1, the second circuit structure CS2, and the plurality of second bonding elements BE2 is released from the carrier and flipped upside down. The plurality of second bonding elements BE2 are then attached to another carrier CR1 through another release layer RL1 (shown in FIG. 5). Then, a plurality of first bonding elements BE1 can be formed on the first circuit structure CS1, thereby forming the cross-sectional structure as shown in FIG. 5. Next, cutting can be performed along the dicing lines CT1, and the release layer RL1 and the carrier CR1 are removed, thereby obtaining a plurality of package structures PS.

According to the package structure PS shown in FIG. 5, the electronic unit EU of the present disclosure includes the first protective layer P1, the second protective layer P2, and the third protective layer P3 surrounding the die DE, and the first encapsulation layer E1 surrounds the first protective layer P1, the second protective layer P2, and the third protective layer P3, thereby enhancing the protective effect on the die DE, and thus improving the reliability of the electronic unit EU and the package structure PS in which it is applied.

Please refer to FIG. 6, which is a partial schematic process view of a method for manufacturing the package structure according to an embodiment of the present disclosure. As shown in FIG. 6, in an embodiment of manufacturing the package structure, before forming the plurality of third metal pillars M3, a plurality of metal bases MB can be formed first to enhance the structural stability of the subsequently formed third metal pillars M3. Specifically, a release layer RL2 can be formed on a carrier CR2 first, and then a plurality of metal bases MB are disposed on the release layer RL2, spaced from each other by a predetermined distance. Then, a third metal pillar M3 can be formed on each metal base MB. Herein, a width W1 of the metal base MB in the direction X can be greater than a width W2 of the third metal pillar M3, so that the formed third metal pillars M3 can be more stable, thereby improving the process yield. After forming the plurality of third metal pillars M3, a plurality of electronic units EU can be attached to the release layer RL2 through an adhesive layer AL, wherein the adhesive layer AL can be, for example (but not limited to), a die attach film (DAF). Then, a first encapsulation layer E1 can be formed, causing the first encapsulation layer E1 to surround the plurality of metal bases MB, the plurality of third metal pillars M3, and the first protective layer P1, the second protective layer P2, and the third protective layer P3 of the electronic unit EU. Next, the first encapsulation layer E1 can be ground to expose an upper surface M1a of the first metal pillar M1 and an upper surface M3a of the third metal pillar M3. In some embodiments, in subsequent process steps, the metal bases MB can be removed through grinding to expose the lower surfaces of the third metal pillars M3, but the present disclosure is not limited thereto. In other embodiments, the metal bases MB may not be removed, so that the metal bases MB are retained in the package structure.

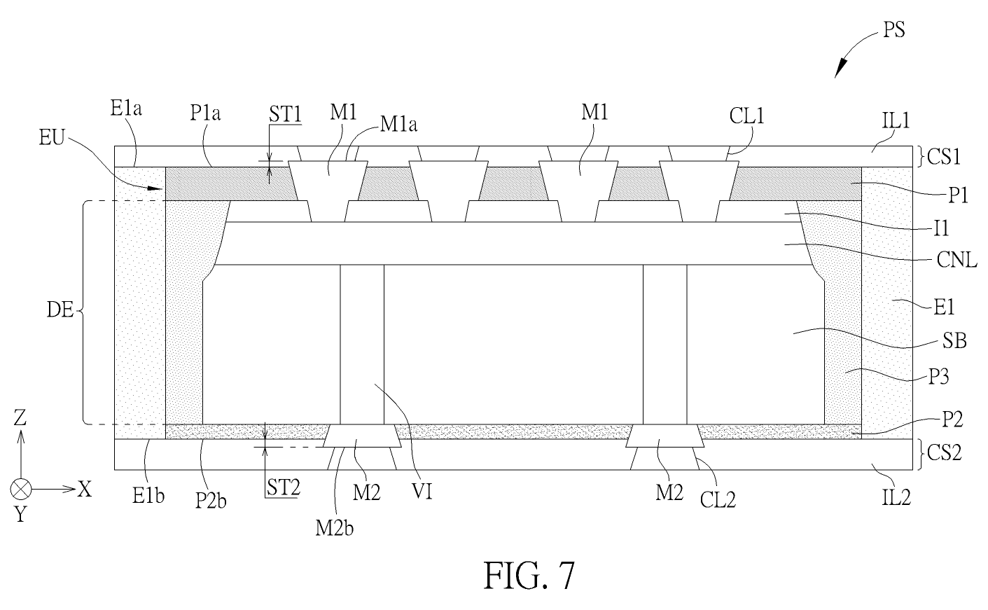

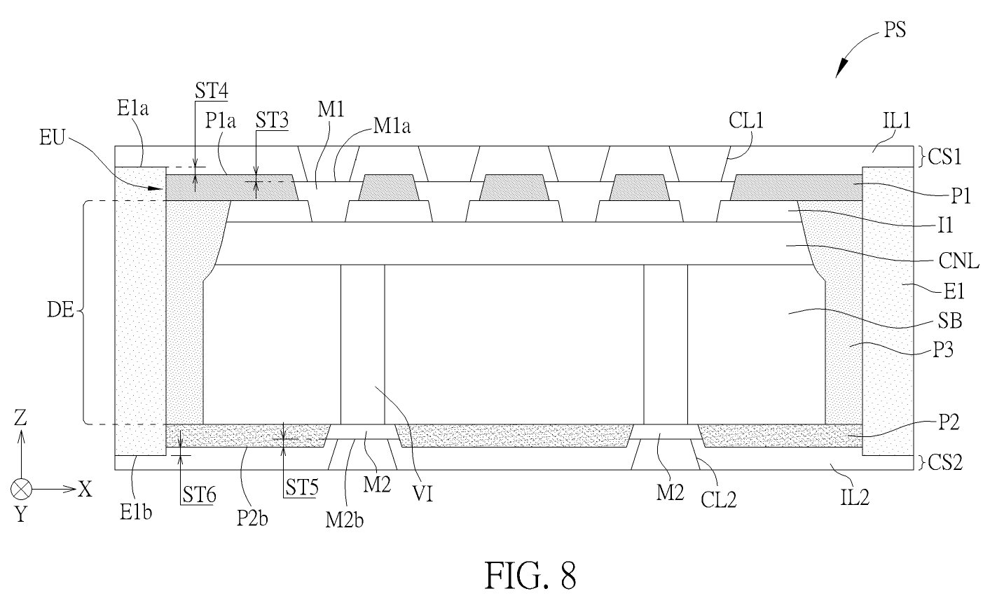

Please refer to FIG. 7, which is a partial schematic cross-sectional view of a package structure according to a second embodiment of the present disclosure. Herein, to simplify the drawing, FIG. 7 (and the subsequent FIG. 8) only shows a partial structure of the package structure PS. FIG. 7 omits the third metal pillars M3, the first bonding elements BE1, and the second bonding elements BE2. The first circuit structure CS1 is shown with only one insulating layer IL1 and one conductive layer CL1, and the second circuit structure CS2 is shown with only one insulating layer IL2 and one conductive layer CL2. According to the package structure PS of the second embodiment shown in FIG. 7, an upper surface M1a of the first metal pillar M1 and an upper surface P1a of the first protective layer P1 may not be coplanar. Specifically, in the direction Z, there can be a height difference between the upper surface M1a of the first metal pillar M1 and the upper surface P1a of the first protective layer P1, forming a step ST1, such that the upper surface M1a protrudes relative to the upper surface P1a. The range of the step ST1 can be greater than or equal to 0.1 micrometers and less than or equal to 1 micrometer. As shown in FIG. 7, the upper surface P1a of the first protective layer P1 can be aligned with an upper surface E1a of the first encapsulation layer E1, that is, the upper surface M1a of the first metal pillar M1 and the upper surface E1a of the first encapsulation layer E1 may not be coplanar. The structural design of the aforementioned step ST1 can achieve an interlocking and/or fixing effect at the interface of the first metal pillar M1, the first protective layer P1, and the insulating layer IL1, thereby enhancing the adhesion between the layers.

As shown in FIG. 7, in some embodiments, a lower surface M2b of the second metal pillar M2 and a lower surface P2b of the second protective layer P2 may not be coplanar. Specifically, in the direction Z, there can be a height difference between the lower surface M2b of the second metal pillar M2 and the lower surface P2b of the second protective layer P2, forming a step ST2, such that the lower surface M2b protrudes relative to the lower surface P2b. The range of the step ST2 can be greater than or equal to 0.1 micrometers and less than or equal to 1 micrometer. As shown in FIG. 7, the lower surface P2b of the second protective layer P2 can be aligned with a lower surface E1b of the first encapsulation layer E1, that is, the lower surface M2b of the second metal pillar M2 and the lower surface E1b of the first encapsulation layer E1 may not be coplanar. The structural design of the aforementioned step ST2 can achieve an interlocking and/or fixing effect at the interface of the second metal pillar M2, the second protective layer P2, and the insulating layer IL2, thereby enhancing the adhesion between the layers.

For example, during the manufacturing process of the package structure PS, a surface treatment can be performed on the first encapsulation layer E1, such as (but not limited to) modifying the surface of the first encapsulation layer E1 through a plasma treatment process to increase the adhesion between layers. Due to the different materials of each layer, the etching rates vary, resulting in the formation of the step ST1 between the upper surface M1a of the first metal pillar M1 and the upper surface P1a of the first protective layer P1, and/or the step ST2 between the lower surface M2b of the second metal pillar M2 and the lower surface P2b of the second protective layer P2 after etching.

In some embodiments, an upper surface of the third metal pillar M3 (shown in FIG. 5) can be coplanar or not coplanar with the upper surface E1a of the first encapsulation layer E1, and/or a lower surface of the third metal pillar M3 can be coplanar or not coplanar with the lower surface E1b of the first encapsulation layer E1. In other embodiments, the upper surface M1a of the first metal pillar M1 can be coplanar with the upper surface P1a of the first protective layer P1 and the upper surface E1a of the first encapsulation layer E1, and/or the lower surface M2b of the second metal pillar M2 can be coplanar with the lower surface P2b of the second protective layer P2 and the lower surface E1b of the first encapsulation layer E1, but is not limited thereto.

Please refer to FIG. 8, which is a partial schematic cross-sectional view of a package structure according to a third embodiment of the present disclosure. The difference between the package structure PS of the third embodiment shown in FIG. 8 and the second embodiment shown in FIG. 7 is that, in the direction Z, an upper surface M1a of the first metal pillar M1 can be lower than an upper surface P1a of the first protective layer P1. Specifically, in the direction Z, there can be a height difference between the upper surface M1a of the first metal pillar M1 and the upper surface P1a of the first protective layer P1, forming a step ST3, such that the upper surface M1a is recessed relative to the upper surface P1a. The range of the step ST3 can be greater than or equal to 0.1 micrometers and less than or equal to 1 micrometer. Furthermore, as shown in FIG. 8, the upper surface P1a of the first protective layer P1 and an upper surface E1a of the first encapsulation layer E1 may not be coplanar, that is, in the direction Z, there can be a height difference between the upper surface P1a of the first protective layer P1 and the upper surface E1a of the first encapsulation layer E1, forming a step ST4. The range of the step ST4 can be greater than or equal to 0.1 micrometers and less than or equal to 1 micrometer. The structural design of the aforementioned step ST4 can achieve an interlocking and/or fixing effect at the interface of the first encapsulation layer E1, the first protective layer P1, and the insulating layer IL1, thereby enhancing the adhesion between the layers.

As shown in FIG. 8, in some embodiments, in the direction Z, there can be a height difference between a lower surface M2b of the second metal pillar M2 and a lower surface P2b of the second protective layer P2, forming a step ST5, such that the lower surface M2b is recessed relative to the lower surface P2b. The range of the step ST5 can be greater than or equal to 0.1 micrometers and less than or equal to 1 micrometer. Furthermore, the lower surface P2b of the second protective layer P2 and a lower surface E1b of the first encapsulation layer E1 may not be coplanar, that is, in the direction Z, there can be a height difference between the lower surface P2b of the second protective layer P2 and the lower surface E1b of the first encapsulation layer E1, forming a step ST6. The range of the step ST6 can be greater than or equal to 0.1 micrometers and less than or equal to 1 micrometer. The structural design of the aforementioned step ST6 can achieve an interlocking and/or fixing effect at the interface of the first encapsulation layer E1, the second protective layer P2, and the insulating layer IL2, thereby enhancing the adhesion between the layers.

According to the embodiment shown in FIG. 8, the materials of the first protective layer P1 and the second protective layer P2 can be different from the material of the first encapsulation layer E1, wherein the materials of the first protective layer P1 and the second protective layer P2 can, for example (but not limited to), include polyimide. Due to the different materials of each layer, the etching rates vary, thus forming the aforementioned steps ST3, ST4, ST5, and/or ST6. Their formation method can be referred to the formation of steps ST1 and ST2 in the foregoing embodiments and will not be repeated here.

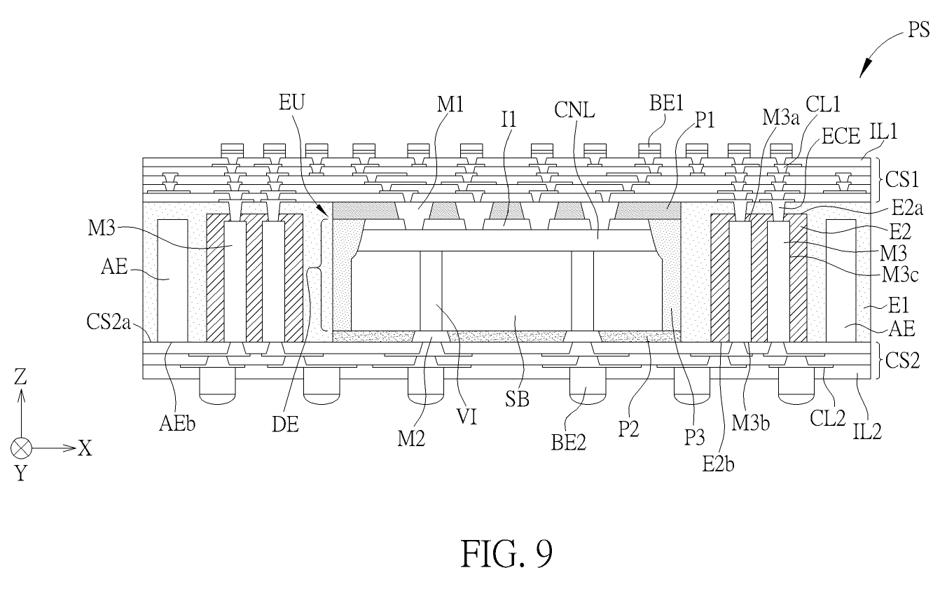

Please refer to FIG. 9, which is a schematic cross-sectional view of a package structure according to a fourth embodiment of the present disclosure. According to the embodiment shown in FIG. 9, the package structure PS can further include a second encapsulation layer E2, surrounding at least one of the plurality of third metal pillars M3, and the first encapsulation layer E1 surrounds the second encapsulation layer E2. For example, the second encapsulation layer E2 can simultaneously surround two third metal pillars M3 to cover the side surfaces M3c of the two third metal pillars M3. In the direction Z, an upper surface M3a of the third metal pillar M3 surrounded by the second encapsulation layer E2 can be lower than an upper surface E2a of the second encapsulation layer E2. Specifically, a portion of the second encapsulation layer E2 can be disposed between the upper surface M3a of the third metal pillar M3 and the first encapsulation layer E1, and a portion of the second encapsulation layer E2 and a portion of the first encapsulation layer E1 can be disposed between the upper surface M3a of the third metal pillar M3 and the first circuit structure CS1. The third metal pillar M3 can be electrically connected to the conductive layer CL1 of the first circuit structure CS1 via a connection element ECE disposed in a through-hole penetrating the second encapsulation layer E2 and the first encapsulation layer E1. Alternatively, in other embodiments, the aforementioned connection element ECE can be formed by one of the conductive layers CL1 of the first circuit structure CS1. The second encapsulation layer E2 surrounding the third metal pillar M3 can enhance the protective effect on the third metal pillar M3, for example, it can reduce the probability of cracking at the interface between the third metal pillar M3 and the first encapsulation layer E1 during processes (such as a grinding process). A lower surface M3b of the third metal pillar M3 surrounded by the second encapsulation layer E2 can be aligned with a lower surface E2b of the second encapsulation layer E2, meaning the second encapsulation layer E2 can expose the lower surface M3b of the third metal pillar M3, such that the lower surface M3b of the third metal pillar M3 can directly contact an upper surface CS2a of the second circuit structure CS2, and the third metal pillar M3 can be electrically connected to the conductive layer CL2 of the second circuit structure CS2.

In the manufacturing process of the package structure PS shown in FIG. 9, for example, a second encapsulation layer E2 can be formed around at least one third metal pillar M3 (e.g., two third metal pillars M3 as shown in FIG. 9) first, so that the third metal pillar M3 is covered on its side surface M3c and upper surface M3a and exposed at its lower surface M3b. Then, the third metal pillar M3 and the second encapsulation layer E2 are attached to a carrier (e.g., the carrier CR2 shown in FIG. 6) through a release layer (e.g., the release layer RL2 shown in FIG. 6). Then, an electronic unit EU can be disposed on the release layer, such that the electronic unit EU is located between at least two third metal pillars M3 surrounded by the second encapsulation layer E2 in the direction X.

As shown in FIG. 9, in some embodiments, the package structure PS can further include an alignment element AE disposed adjacent to the plurality of third metal pillars M3, and the first encapsulation layer E1 surrounds the alignment element AE. In the direction X, the third metal pillar M3 can be located between the alignment element AE and the electronic unit EU, that is, at least one third metal pillar M3 can be disposed on opposite sides of the electronic unit EU, and an alignment element AE can be disposed on a side of the third metal pillar M3 opposite to the electronic unit EU. The second circuit structure CS2 can be disposed on one side of the electronic unit EU, the plurality of third metal pillars M3, and the alignment element AE (e.g., the lower side as shown in FIG. 9), and a lower surface AEb of the alignment element AE can contact an upper surface CS2a of the second circuit structure CS2. The alignment element AE can be electrically isolated from the first circuit structure CS1 and the second circuit structure CS2. In some embodiments, the alignment element AE can be composed of a body and a marking structure (not shown). The material of the body can include silicon, glass, invar alloy, silicon carbide (SiC), or a combination of the above materials, but is not limited thereto. The material of the marking structure can include a metal material, such as copper, aluminum, titanium, tungsten, or a combination of the above materials, so that there is a structural difference, a reflectance difference, a material difference, or a color difference between the marking structure and the body, thereby improving the identification accuracy of the marking structure.

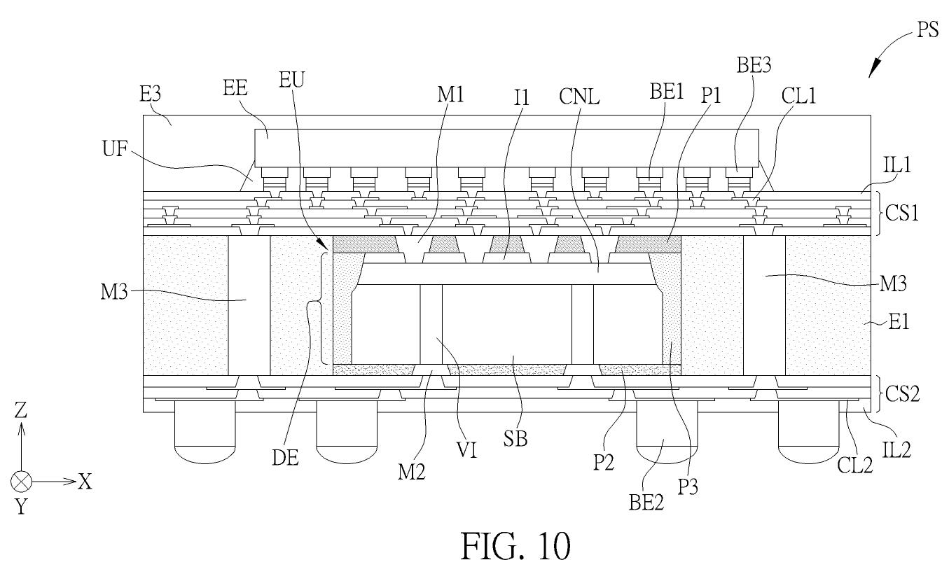

Please refer to FIG. 10, which is a schematic cross-sectional view of a package structure according to a fifth embodiment of the present disclosure. According to the embodiment shown in FIG. 10, the package structure PS can further include an electronic component EE and a third bonding element BE3. The electronic component EE can be disposed on the first circuit structure CS1, and a plurality of third bonding elements BE3 can be disposed on one side of the electronic component EE. The electronic component EE can be electrically connected to the first bonding elements BE1 disposed on one side of the first circuit structure CS1 through the plurality of third bonding elements BE3, and electrically connected to the electronic unit EU and/or the third metal pillars M3 through the first bonding elements BE1 and the first circuit structure CS1. In some embodiments, as shown in FIG. 10, the package structure PS can further include a third encapsulation layer E3 and an underfill layer UF. The third encapsulation layer E3 can surround the electronic component EE to block moisture, and the underfill layer UF can be disposed between the first circuit structure CS1 and the electronic component EE to cover the first bonding elements BE1 and the third bonding elements BE3, but is not limited thereto.

In summary, according to the package structure and its electronic unit of the embodiments of the present disclosure, by providing a first protective layer, a second protective layer, and a third protective layer surrounding a die in the electronic unit, and a first encapsulation layer surrounding the first protective layer, the second protective layer, and the third protective layer, the protective effect on the die can be enhanced, thereby improving the reliability of the electronic unit and the package structure in which it is applied. Furthermore, by designing the edge of the die to have a recess, or by designing the surface of the metal pillars of the electronic unit to be not coplanar with the surface of the protective layer and/or the surface of the first encapsulation layer, the adhesion between the layers can be increased.

The foregoing has outlined features of several embodiments so that those skilled in the art may better understand the aspects of the present disclosure. Those skilled in the art should appreciate that the disclosure provides a basis for designing or modifying other processes and structures for carrying out substantially the same functions and/or achieving substantially the same results as the embodiments introduced herein. Furthermore, such equivalent configurations do not depart from the spirit and scope of the present disclosure, and various changes, substitutions, and alterations can be made herein without departing from that spirit and scope.

What is claimed is:

1. A package structure, comprising:
an electronic unit, comprising:
a die, having a first surface, a second surface, and a side surface, wherein the first surface is opposite to the second surface, and the side surface connects the first surface and the second surface;
a first protective layer, a second protective layer, and a third protective layer, surrounding the die;
a first metal pillar disposed on the first surface and electrically connected to the die; and
a second metal pillar disposed on the second surface and electrically connected to the die;
a plurality of third metal pillars disposed on at least one side of the electronic unit; and
a first encapsulation layer surrounding the first protective layer, the second protective layer, and the third protective layer.

2. The package structure of claim 1, wherein the third protective layer surrounds the side surface of the die.

3. The package structure of claim 1, wherein the first protective layer covers the first surface, the second protective layer covers the second surface, the first protective layer exposes the first metal pillar, and the second protective layer exposes the second metal pillar.

4. The package structure of claim 1, wherein the first protective layer, the second protective layer, and the third protective layer comprise an organic material.

5. The package structure of claim 1, wherein a ratio of a thickness of the first protective layer to a thickness of the die is greater than or equal to 0.05 and less than or equal to 0.6.

6. The package structure of claim 1, wherein the die comprises a first insulating layer, an outer surface of the first insulating layer is the first surface, and the first protective layer is disposed on the outer surface of the first insulating layer.

7. The package structure of claim 6, wherein a Young's modulus of the first protective layer is less than a Young's modulus of the first insulating layer.

8. The package structure of claim 1, wherein an upper surface of the first metal pillar and an upper surface of the first protective layer are not coplanar.

9. The package structure of claim 1, wherein an upper surface of the first metal pillar and an upper surface of the first encapsulation layer are not coplanar.

10. The package structure of claim 1, further comprising a second encapsulation layer surrounding at least one of the plurality of third metal pillars, wherein the first encapsulation layer surrounds the second encapsulation layer.

11. The package structure of claim 2, wherein an edge of the die has a recess, and the third protective layer contacts a surface of the recess.

12. The package structure of claim 6, wherein the first insulating layer comprises an inorganic material.

13. The package structure of claim 6, wherein the die further comprises a second insulating layer, an outer surface of the second insulating layer is the second surface, and the second protective layer is disposed on the outer surface of the second insulating layer.

14. The package structure of claim 8, wherein in a normal direction of the first surface, a step is formed between the upper surface of the first metal pillar and the upper surface of the first protective layer, and a range of the step is greater than or equal to 0.1 micrometers and less than or equal to 1 micrometer.

15. The package structure of claim 1, wherein a lower surface of the second metal pillar and a lower surface of the second protective layer are not coplanar.

16. The package structure of claim 1, wherein a lower surface of the second metal pillar and a lower surface of the first encapsulation layer are not coplanar.

17. The package structure of claim 10, wherein an upper surface of the at least one of the plurality of third metal pillars is lower than an upper surface of the second encapsulation layer.

18. The package structure of claim 10, wherein a portion of the second encapsulation layer is disposed between an upper surface of the at least one of the plurality of third metal pillars and the first encapsulation layer, and the second encapsulation layer exposes a lower surface of the at least one of the plurality of third metal pillars.

19. The package structure of claim 1, further comprising an alignment element disposed adjacent to the plurality of third metal pillars, wherein the first encapsulation layer surrounds the alignment element.

20. The package structure of claim 19, further comprising a second circuit structure disposed on one side of the electronic unit, the plurality of third metal pillars, and the alignment element, wherein a lower surface of the alignment element contacts an upper surface of the second circuit structure.
